(19) United States
(12) Patent Application Publication
(10) Pub. No.: US 2020/0348338 A1
(43) Pub. Date: Nov. 5, 2020

(54) TEST PIN CONTACT BUFFER

(71) Applicant: APEX PROBES TECHNOLOGY CO., LTD., Zhubei City (TW)

(72) Inventors: MING-DAO WU, ZHUBEI CITY (TW); SHIH-HUNG LO, ZHUBEI CITY (TW); FU-CHENG CHUANG, ZHUBEI CITY (TW); ZHAO-YUAN TSAI, ZHUBEI CITY (TW); HAO-WEN CHIEN, ZHUBEI CITY (TW); BOR-CHEN TSAI, ZHUBEI CITY (TW); CHIH-FENG CHEN, ZHUBEI CITY (TW)

(21) Appl. No.: 16/398,290

(22) Filed: Apr. 30, 2019

(51) Int. Cl. G01R 1/067

(52) U.S. Cl. CPC G01R 1/06744

(57) ABSTRACT

A test pin contact buffer, fixed to a test pin base, is a sheet-like structure made of a composite material including a conductive material and an insulating material, and defines at least one contact area corresponding to at least one test pin of the test pin base. The contact area has at least one cutout hole, an insulating deformation structure and a conductive head structure. The insulating deformation structure is extendable and made of the insulating material and extends outward from the conductive head structure. The cutout hole enables the contact area to be in a partial hollow state, which is beneficial for deformation of the insulating deformation structure. The test pin can be used for performing measurement in an indirect manner, reducing the wear of the test pin, prolonging the service life, and improving the measurement speed and efficiency.

### FIELD OF THE INVENTION

The present invention relates to an electrical detection device, and more particularly to a test pin contact buffer which is disposed on a test pin base to prolong the service life of a test pin and reduce the maintenance time to improve the test speed and the yield.

### BACKGROUND OF THE INVENTION

In recent years, with the advancement of technology, the semiconductor industry is growing rapidly. In order to maintain the quality of the products, after the semiconductor components are manufactured, relevant tests must be performed to ensure that the electrical and signal transmission of each product meets the requirements.

A probe card is a semiconductor component detection device which is quite common and easy to use. The probe card is generally composed of a test pin and a base (or a jig). The test pin is disposed on the base according to the position of an object to be tested for detecting the object. In a conventional detection method, each test pin on the probe card is configured to get contact with the object to be tested many times. During this process, the detecting end of the test pin is constantly in contact with the object to be tested, which may cause the detecting end of the test pin to be easily worn. After a period of time, the contact area between the detecting end of the test pin and the object to be tested is continuously enlarged. As a result, the contact resistance increases to affect the detection result and to reduce the detection accuracy. The replacement speed of the test pin is also increased, resulting in an increase in the installation cost. On the other hand, when the test pin is worn out due to use, it is necessary to disassemble the damaged test pins one by one for replacement or adjustment. It takes a lot of time and manpower to repair the probe card.

Accordingly, the inventor of the present invention has devoted himself based on his many years of practical experiences to solve these problems, how to effectively improve the detection speed and accuracy and reduce the wear of the test pin. Therefore, a test pin contact buffer is developed. The test pin contact buffer can protect test pins from external components, conductive dust and electrical interference.

### SUMMARY OF THE INVENTION

The primary object of the present invention is to provide a test pin contact buffer, which can prolong the service life of a test pin effectively and improve the convenience of maintenance and replacement.

The invention is to provide a test pin contact buffer, fixedly connected to a test pin base, for the test pin base to perform electrical or signal detection for an object to be tested, the test pin base having at least one test pin, the test pin having a detecting end, characterized by: the test pin contact buffer being a sheet-like structure made of a composite material including a conductive material and an insulating material, the test pin contact buffer defining at least one contact area corresponding to the test pin, the contact area having at least one cutout hole, an insulating deformation structure and a conductive head structure, the insulating deformation structure being extendable and made of the insulating material and extending outward from the conductive head structure, the cutout hole enabling the contact area to be in a partial hollow state to facilitate extension and deformation of the insulating deformation structure, a first side of the conductive head structure being in close contact with the detecting end, an opposite second side of the conductive head structure being in contact with the object to be tested when actuated; wherein after the test pin contact buffer is mounted to the test pin base, the detecting end of the test pin is pressed against and in normal contact with the first side of the conductive head structure, and the insulating deformation structure is deformed into a three-dimensional shape due to the conductive head structure under stress. Through the test pin protective structure provided by the present invention, when the test pin is to detect an object to be tested, a conductive head structure which is in normal contact with a detecting end is used as a buffer medium to form electrical signal conduction. In this way, the wear caused by the test pin repeatedly contacting the object to be tested can be reduced, and the service life of the test pin can be prolonged effectively.

### BRIEF DESCRIPTION OF THE DRAWINGS

FIG. 1 is a planar schematic view of the test pin contact buffer in accordance with a first embodiment of the present invention;

FIG. 2 is another planar schematic view of the test pin contact buffer in accordance with the first embodiment of the present invention;

FIG. 3 is a schematic view showing the practical application after the test pin contact buffer is mounted to the test pin base in accordance with the first embodiment of the preferred embodiment;

FIG. 4 is a planar schematic view of the test pin contact buffer in accordance with a second embodiment of the present invention;

FIG. 5 is a schematic view showing the application after the test pin contact buffer is mounted to the test pin base in accordance with a third embodiment of the preferred embodiment.

FIG. 6 is a planar schematic view of the test pin contact buffer in accordance with a fourth embodiment of the present invention;

FIG. 7 is a planar schematic view of the test pin contact buffer in accordance with a fifth embodiment of the present invention; and

FIG. 8 is a planar schematic view of the test pin contact buffer in accordance with a sixth embodiment of the present invention.

### DETAILED DESCRIPTION OF THE PREFERRED EMBODIMENTS

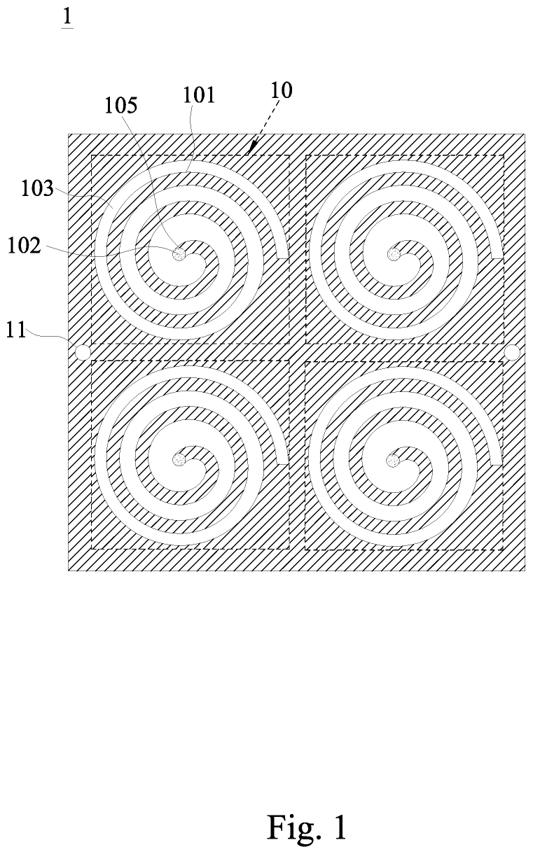

Embodiments of the present invention will now be described, by way of example only, with reference to the accompanying drawings. Referring to FIGS. 1 to 5, the present invention discloses a test pin contact buffer 1 fixedly connected to a test pin base 2 for the test pin base 2 to perform electrical or signal detection for an object 3 to be tested. The test pin base 2 is provided with at least one test pin 20. The test pin 20 has a detecting end 201. The detecting end 201 of the test pin 20 extends out of the test pin base 2. An end of the test pin 20, opposite to the detecting end 201, is electrically connected to a detection machine (not shown) to receive the electrical status and signals. The test pin base 2 is provided with at least one test pin tube 21 for accommodating the test pin 20. The test pin 20 may be a vertical pogo pin, a horizontal cantilever test pin or a micro electro mechanical system (MEMs) test pin. In this embodiment, for example, the test pin 20 is a vertical pogo pin. However, the test pin contact buffer 1 may be applied to various test pins, not limited thereto, such as a vertical pin structure having an elastic force.

The test pin contact buffer 1 is characterized in that it is a sheet-like structure made of a composite material including a conductive material and an insulating material. Preferably, it is a film sheet. The test pin contact buffer 1 defines at least one contact area 10 corresponding to the test pin 20, that is, one contact area 10 corresponds to one test pin 20. The contact area 10 has an insulating deformation structure 101, a conductive head structure 102, and at least one cutout hole 103. Preferably, the conductive head structure 102 is located at the center of the contact area 10. The insulating deformation structure 101 is extendable and made of the insulating material and extends outward from the conductive head structure 102. The cutout hole 103 enables the contact area 10 to be in a partial hollow state to facilitate extension and deformation of the insulating deformation structure 101, that is, the contact area 10 is proved with the cutout hole 103 to form the insulating deformation structure 101. One side of the conductive head structure 102 is in close contact with the detecting end 201, and the other side of the conductive head structure 102 is configured to get contact with the object 3 to be tested when actuated for detection.

After the test pin contact buffer 1 is mounted to the test pin base 2, the detecting end 201 of the test pin 20 is pressed against and in normal contact with one side of the conductive head structure 102. The insulating deformation structure 101 is deformed into a three-dimensional shape due to the conductive head structure 102 under stress to form a sheathed structure relative to the test pin 20, thereby retaining the position of the test pin contact buffer 1 and the test pin 20, so that the conductive head structure 102 is kept in contact with the detecting end 201. Wherein, if the test pin contact buffer 1 cooperates with the test pin 20 that is a vertical pin structure having an elastic force, the restoring force of the test pin 20 is greater than that of the insulating deformation structure 101.

Through the cutout hole 103, after assembled, the insulating deformation structure 101 may be deformed by the press of the test pin 20 to surround the detecting end 201. The insulating deformation structure 101 allows the test pin contact buffer 1 to be in normal contact with the test pin 20. The detecting end 201 is not insulated from the area of the conductive head structure 102. Based on this assembled result, when the test pin base 2 approaches the object 3 to be tested for detection, the conductive head structure 102 of the test pin contact buffer 1 is first in direct contact with the object 3 to be tested. The post-buffer stroke is continued by the test pin 20. In the electrical or signal detection, the two sides of the conductive head structure 102 respectively contact the test pin 20 and the object 3 to be tested to form conduction. Therefore, the detecting end 201 of the test pin 20 does not always touch and leave the object, thereby effectively preventing the detecting end 201 of the test pin 20 from being damaged due to continuous contact with the object 3 to be tested. The service life of the test pin 20 can be prolonged.

In particular, through the limitation of the direct contact between the conductive head structure 102 and the test pin 20, the present invention avoids complicated signal and electrical transmission, and has more accurate detection results and detection efficiency, and can reduce the setup cost and manufacturing difficulty effectively. In the case of damage, only the test pin contact buffer 1 needs to be disassembled for replacement, and the test pin base 2 and the test pin 20 and the like are not required to be changed, thereby improving the speed of replacement and repair. The overall detection cost can be relatively reduced. The invention is made of a composite material that is both insulating and electrically conductive. Only the area corresponding to the detecting end 201 of the test pin 20 is made of the conductive material, so that the test pin 20 and the object 3 to be tested form signal and electrical conduction. The rest is made of the non-conductive insulating material to avoid a short circuit of the test pin 20 during detection.

In addition, the number of the test pins 20 may be up to tens or even tens of thousands. The test pins 20 may be uneven in height due to their own tolerance or the error after being placed on the test pin base 2. By adjusting the thickness of the conductive head structure 102, after the test pin contact buffer 1 of the present invention is mounted to the test pin base 2, the detecting ends 201 that are not of equal horizontal height can be kept in normal contact with the conductive head structure 102 to protect the test pins 20 surely.

In this embodiment, the test pin base 2 is provided with a plurality of the test pins 20. The test pin contact buffer 1 defines a plurality of contact areas 10 corresponding to the test pins 20, such that one contact area 10 corresponds to one of the test pins 20. In order to facilitate the illustration, four contact areas 10 are shown in the drawings, and the contact areas 10 are arranged in the same manner. Actually, the contact areas 10 are set according to the arrangement interval and position of the test pins 20. The test pin contact buffer 1 can adjust the thickness of the corresponding conductive head structure 102 according to the level of the detecting ends 201, so that each of the detecting ends 201 maintains normal contact with the corresponding conductive head structure 102.

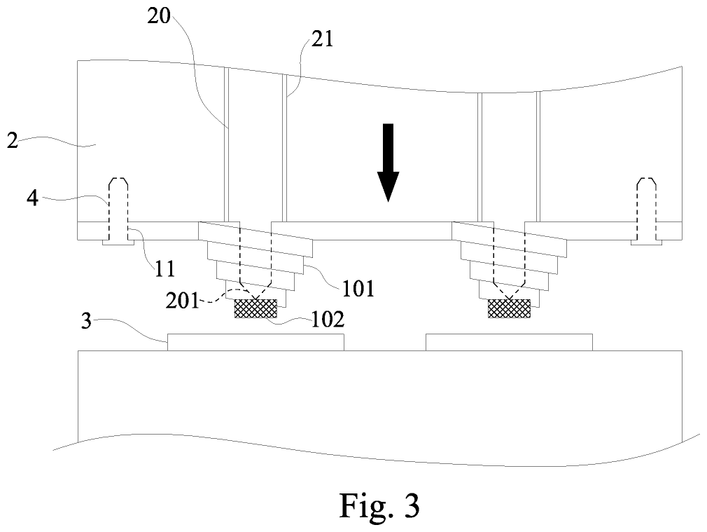

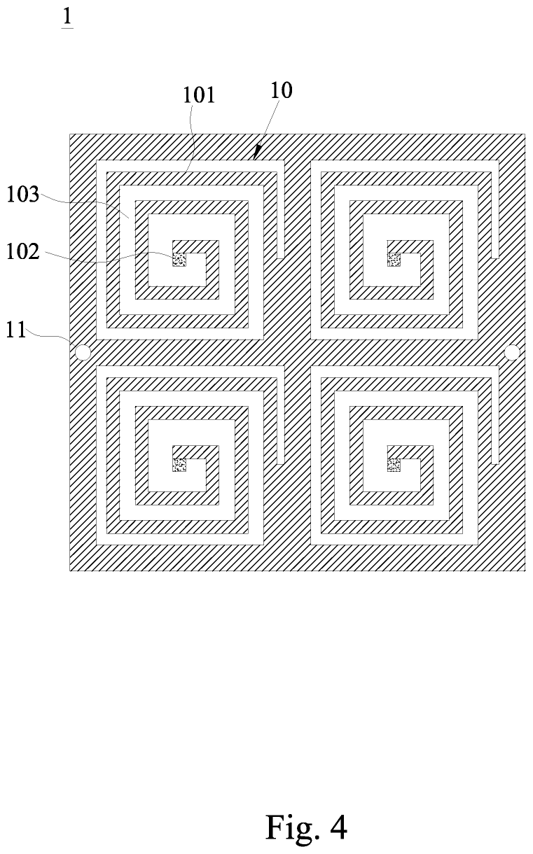

After the test pin contact buffer 1 is mounted to the test pin base 2, in order to allow the insulating deformation structures 101 to be smoothly protruded toward the respective test pins 20 by the pressing action of the test pins 20, the cutout hole 103 may have a spiral shape. The insulating deformation structure 101 is in the form of a sheet-like spiral structure corresponding to the cutout hole 103 having the spiral shape. The conductive head structure 102 is located at the distal end of the spiral structure, that is, at the spiral center of the insulating deformation structure 101. After the insulating deformation structure 101 is deformed, the insulating deformation structure 101 changes from the sheet-like spiral structure to a three-dimensional spiral structure under stress to surround the detecting end 201, and is gradually reduced from the test pin 20 toward the conductive head structure 102. The insulating deformation structure 101 may be arranged in an equal width to have a better deformation effect. As to the term “surround”, because the insulating deformation structure 101 is spiral, when it is deformed due to the pressing force of the conductive head structure 102, it will exhibit a multi-coil deformation state which is tapered from top to bottom as a spring. At this time, the insulating deformation structure 101 surrounds the outer side of the detecting end 201. The insulating deformation structure 101 may have spiral coils that are in close contact with each other as shown in FIG. 3, or that are spaced a determined distance apart from each other. The cutout hole 103 may be a circular spiral or a square spiral. As shown in FIG. 4, the cutout hole 103 is in the form of a square spiral structure. The insulating deformation structures 101 may be formed by means of semiconductor processing or laser machining.

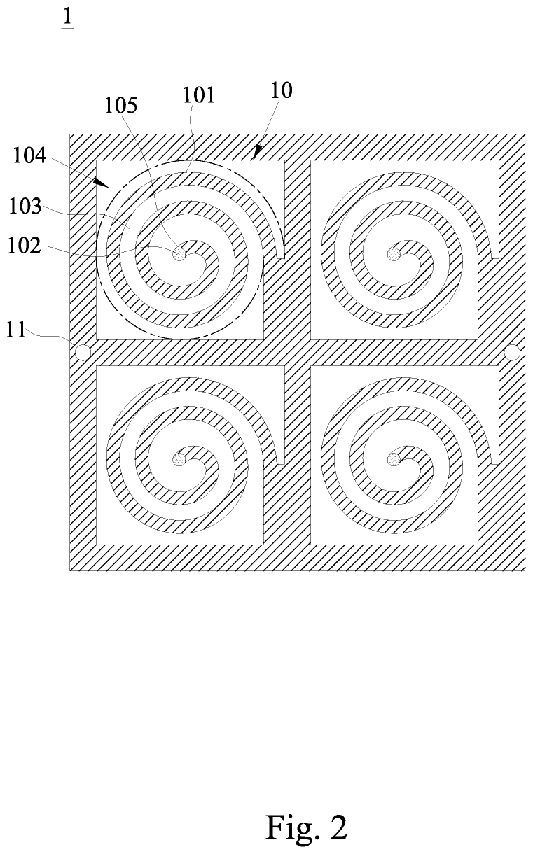

Furthermore, for the insulating deformation structure 101 of each contact area 10 to be deformed and to retain the test pin 20 according to various test pins 20, the contact area 10 further has at least one enlarged through hole 104. The enlarged through hole 104 is formed by extending the cutout hole 103 outwardly and is in communication with the cutout hole 103. FIG. 2 is a schematic view showing that the test pin contact buffer 1 is provided with the enlarged through hole 104 in accordance with the first embodiment. That is, the area occupied by the cutout hole 103 can be enlarged via the enlarged through hole 104, which is more favorable for the deformation of the insulating deformation structure 101. In this embodiment, a part of the enlarged through hole 104 extends to the edge of the contact area 10 as an example.

In addition, in order to combine the conductive head structure 102 made of the conductive material and the insulating deformation structure 101 made of the insulating material, the contact area 10 is formed with a predetermined perforation 105 filled with the conductive material to form the conductive head structure 102. The conductive material is fixed to the predetermined perforation 105 through an insulating adhesive (not shown), so that the test pin contact buffer 1 is made of a composite material. The predetermined perforation 105 may be in a square or circular shape. As shown in FIG. 4, the predetermined perforation 105 is a square hole. In addition, the area of the conductive head structure 101 may be greater than the cross-sectional area of the detecting end 201 of the test pin 20, so that the detecting end 201 is in positive contact with the conductive head structure 101. More specifically, in practice, the contact area 10 is first formed with the predetermined perforation 105 relative to the corresponding test pin 20. The inside of the predetermined perforation 105 is coated with the insulating adhesive and filled with the conductive material, and the conductive material is fixed in the predetermined perforation 105 to form the conductive head structure 102, and then the insulating deformation structure 10 is formed by means of semiconductor processing or laser machining.

In order to facilitate the alignment of the test pin contact buffer 1 to the test pin base 2, and for the test pin contact buffer 1 to be adjustable relative to the test pin base 2, preferably, the test pin contact buffer 1 has at least one locking hole 11. The locking hole 11 is located adjacent to the edge of the test pin contact buffer 1. The test pin contact buffer 1 is locked to the test pin base 2 by at least one locking member 4. The test pin 20 can be quickly aligned with the conductive head structure 102 through the locking hole 11, having high assembly efficiency. The tightness of the contact between the test pin 20 and the conductive head structure 102 can be adjusted by the locking strength of the locking member 4 to avoid the problem of poor contact. This embodiment has a plurality of locking holes 11 that are located adjacent to the circumference of the test pin contact buffer 1 as an example.

In the application, as shown in FIG. 3, after the test pin contact buffer 1 is mounted to the test pin base 2, the detecting end 201 of each test pin 20 corresponds to each conductive head structure 102 and applies a pressure to the conductive head structure 102. At this time, the insulating deformation structure 101 is deformed in the vertical direction under pressure to form a three-dimensional spiral structure and partially cover the detecting end 201, so that the conductive head structure 102 is in normal contact with the detecting end 201. When the test pin base 2 is to detect the object 3 to be tested, the test pin base 2 is brought close to the object 3 to be tested, and the conductive head structure 102 is brought into contact with the object 3 to be tested, and the detecting end 201 of the test pin 20 is electrically connected to the object 3 to be tested through the conductive head structure 102 for performing the related detection. Wherein, the protruding height of the insulating deformation structure 101 after deformation is less than or equal to one quarter of the movable stroke of the test pin 20. For example, when the movable stroke of the test pin 20 is 0.4 mm, the protruding height of the insulating deformation structure 101 may be designed to be about 0.1 mm or less for better detection performance. The drawings are only a preferred illustration of the invention and do not represent the actual structural size ratio.

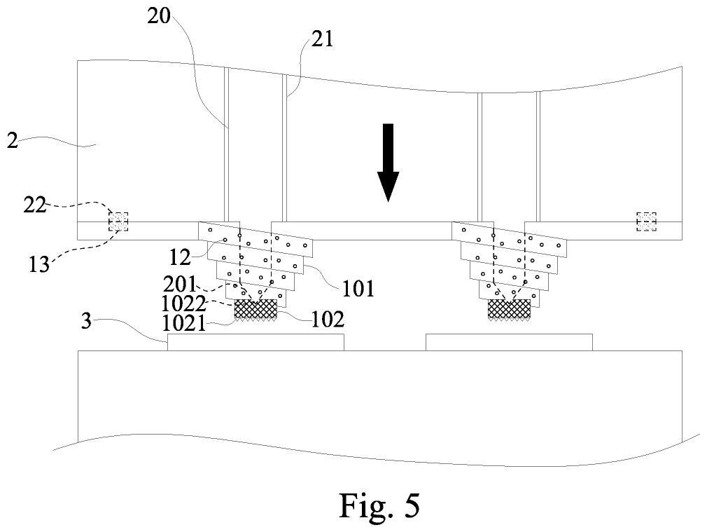

In addition, as shown in FIG. 5, when the object 3 is detected, the oxide layer or other deposits on the surface of the object 3 may affect the conduction between the object 3 and the test pin 20 to further affect the detection result. Therefore, a plurality of microstructures 1021 are disposed on the side that is in contact with the object 3 to be tested of the conductive head structure 102. Each of the microstructures 1021 has a tip for piercing the oxide layer or the deposits on the surface of the object 3 to be tested when in contact with the object 3 to be tested, so that the conductive head structure 102 and the detecting end 201 are surely in contact with the object 3 to be tested. In this embodiment, each of the microstructures 1021 is a tapered structure as an example. The microstructures 1021 may be dispersed on the surface of the conductive head structure 102 or may be arranged in a matrix on the surface of the conductive head structure 102. The dimensions of the microstructures 1021 depicted in FIG. 5 are for illustrative purposes. In practice, the microstructures 1021 are of a very small size.

In addition, in order to enhance the contact stability of the conductive head structure 102 and the detecting end 201, the hardness of the conductive head structure 102 is less than the hardness of the detecting end 201 so that the detecting end 201 is pressed against the conductive head structure 102 in a piercing manner. When the detecting end 201 pierces the conductive head structure 102, the conductive head structure 102 is correspondingly formed with at least one micro recess 1022. That is, the material of the conductive head structure 102 having a hardness less than that of the detecting end 201 is selected. When the detecting end 201 is in contact with the conductive head structure 102, the conductive head structure 102 is correspondingly formed with the micro recess 1022, so that the electrical conduction during the detection can be transmitted to the detecting end 201 along the inner surface of the micro recess 1022 via the conductive head structure 102 to complete the conduction detection. In this embodiment, the hardness of the conductive head structure 102 is less than the hardness of the detecting end 201 as an example.

Preferably, the depth of the micro recess 1022 is 10% to 75% of the thickness of the conductive head structure 102 to have better positioning and retaining contact performance. If the micro recess 1022 is too shallow, the detecting end 201 is easy to slip relative to the conductive head structure 102 to lose protection performance. If the micro recess 1022 is too deep, the conductive head structure 102 itself is insufficient in rigidity, and the detecting end 201 easily passes through the conductive head structure 102 when in use. In this embodiment, the depth of the micro recess 1022 is 25% of the thickness of the conductive head structure 102 as an example.

In addition, in order to improve the performance at the time of detection, preferably, the inside of the insulating deformation structure 101 may be mixed with a plurality of metal particles 12 or a plurality of graphene particles. The metal particles 12 and the graphene particles are covered by the insulating material to block electromagnetic interference and radio frequency interference during detection. Electromagnetic interference (EMI) or radio frequency interference (RFI) may occur during the detection of electrical conduction. In order to reduce the influence of the phenomenon on the detection, the metal particles 12 or the graphene particles may be added into the insulating deformation structure 101 to achieve electromagnetic shielding effect through the metal particles 12 or the graphene particles. Because the metal particles 12 or the graphene particles are covered in the insulating material, they are not electrically connected to the test pin 20 and are still insulated from the test pin 20, thereby preventing a short circuit effectively.

In addition to assembling the test pin contact buffer 1 through the locking hole 11, the test pin contact buffer 1 further has a first magnetic assembly 13 disposed outside the contact area 10, and the test pin base 2 has a second magnetic assembly 22. The test pin contact buffer 1 is magnetically coupled to the test pin base 2, so that the conductive head structure 102 is aligned with and fixed to the detecting end 201 to achieve the effect of quick alignment mounting.

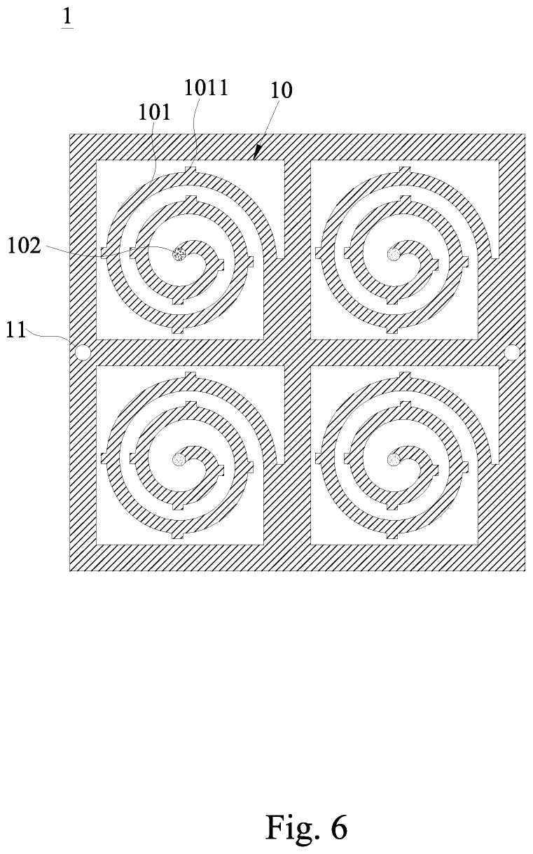

Referring to FIG. 6, when the cutout hole 103 is spiral and the insulating deformation structure 101 is a spiral structure, the insulating deformation structure 101 further has at least one raised positioning portion 1011. The raised positioning portion 1011 extends from the edge of the insulating deformation structure 101 toward the cutout hole 103 to prevent the left and right displacement of the insulating deformation structure 101 from being excessive when the test pin 20 is pressed against the conductive head structure 102, as a result, the test pin 20 and the conductive head structure 102 cannot be in positive contact with each other. When the test pin 20 is pressed against the conductive head structure 102, the raised positioning portion 1011 provides a resisting action during the deformation of the insulating deformation structure 101, preventing the insulating deformation structure 101 from being skewed when deformed to result in that the detecting end 201 is not in positive contact with the conductive head structure 102. The shape of the raised positioning portion 1011 is determined according to the size of the cutout hole 103, such as a square, a rectangle or a semicircle. The length of the raised positioning portion 1011 may be between 50% and 100% of the width of the cutout hole 103, so that the raised positioning portion 1011 spans the cutout hole 103 to get contact with the insulating deformation structure 101 to achieve the blocking effect. Besides, the thickness of the raised positioning portion 1011 is equal to the thickness of the insulating deformation structure 101, about several micrometers or several centimeters.

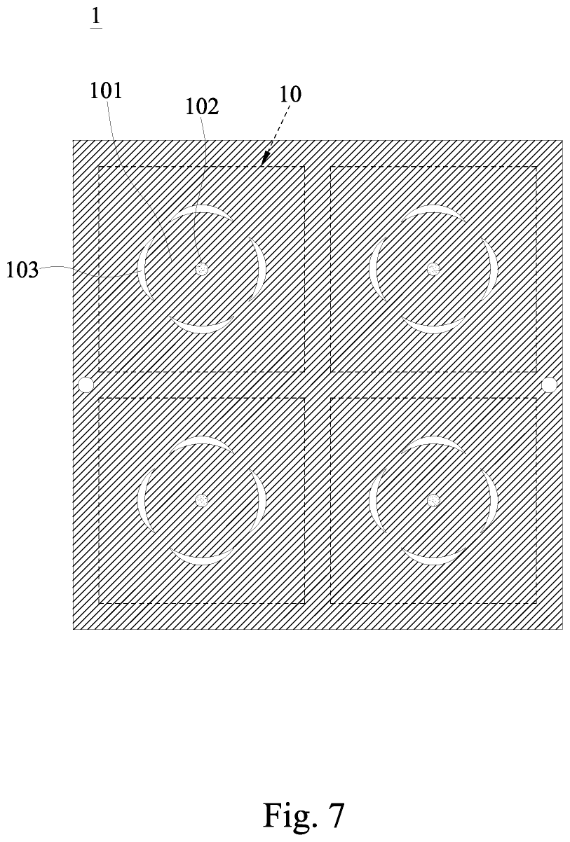

Referring to FIG. 7 in conjunction with the foregoing embodiments, the same technical features are not described herein again, and the same components are denoted by the same reference numerals. As described above, in addition to that the insulating deformation structure 101 is a spiral structure corresponding to the shape of the cutout hole 103, the insulating deformation structure 101 may be disposed as the following form. In this embodiment, each contact area 10 has a plurality of cutout holes 103 that surround the conductive head structure 102 and are spaced apart to form a circle or a rectangle. Through the cutout holes 103, the insulating deformation structure 101 can be more deformed under stress, and the insulating deformation structure 101 protrudes from the surface of the test pin contact buffer 1. Preferably, the cutout holes 103 are in the form of arcs and are arranged at equal intervals around the conductive head structure 102 to form a circle, or the cutout holes 103 may be rectangular, L-shaped and arranged around the conductive head structure 102 to form a rectangle.

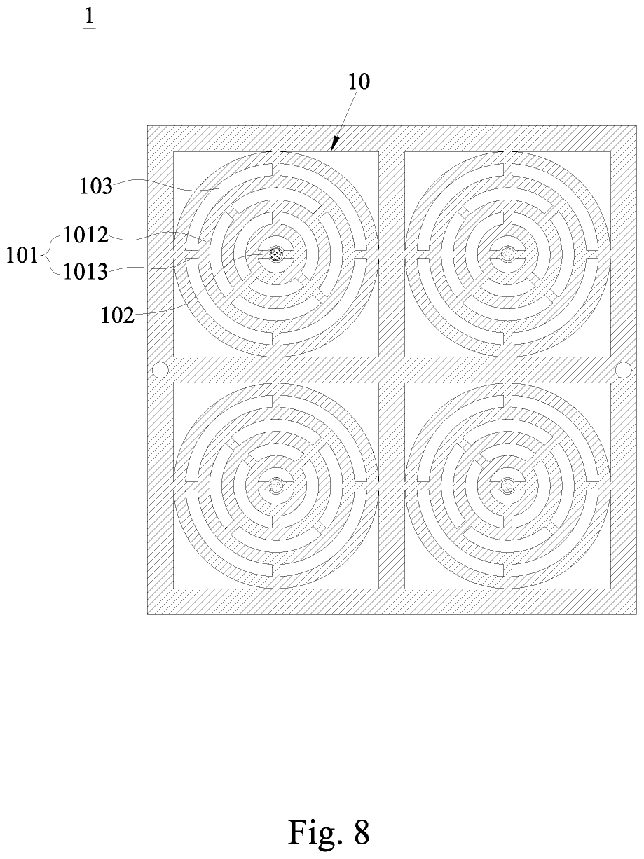

Referring to FIG. 8, in addition to the foregoing, the insulating deformation structure 101 may be in the form described below. When the cutout holes 103 are arranged in the form of a plurality of circles, the insulating deformation structure 101 has a plurality of annular portions 1012 and a plurality of connecting portions 1013. One of the annular portions 1012 is connected to the conductive head structure 102, and the other annular portions 1012 are spaced and arranged outwardly in a concentric manner. Every two of the annular portions 1012 are connected through at least one of the connecting portions 1013. A corresponding one of the cutout holes 103 is disposed between every adjacent two of the annular portions 1012. Through the multi-layer concentric structure, when the detecting end 201 of the test pin 20 is pressed against the conductive head structure 102, the insulating deformation structure 102 is deformed in a convex state under pressure to retain the relative position of the conductive head structure 102 and the detecting end 201 and keep the two in normal contact. Of course, in addition to the concentric circular shape as shown in the drawing, the outermost annular portion 1012 is continuously provided with the connecting portion 1013 that is connected to the edge of the contact area 10. That is, the outermost portion of the insulating deformation structure 101 is the connecting portion 1013 to form a cutout with the edge of the contact area 10. Similarly, the additional technical features described in the above embodiments are also applicable to the implementation in which the insulating deformation structure 101 is concentric. For example, the test pin contact buffer 1 is provided with the locking hole 11, or the conductive head structure 102 is provided with the microstructures 1021 on the side that is in contact with the object 3 to be tested. For the rest of the details, please refer to the above.

In summary, after the test pin contact buffer 1 of the present invention is mounted to the test pin base 2, the test pin contact buffer 1 is located between the test pin 20 and the object 3 to be tested. The test pin 20 is covered by the insulating deformation structure 101 that has the cutout hole 103 and is deformed into a three-dimensional structure under stress, and the detecting end 201 of the test pin 20 is in normal contact with the conductive head structure 102, achieving insulation to prevent a short circuit. The test pin 20 performs detection in an indirect manner, which effectively reduces the wear caused by the direct contact with the object 3 to be tested when the test pin 20 performs the detection operation and prolongs the service life of the test pin 20. In particular, the test pin contact buffer 1 of the present invention is made of a composite material as a whole, and the design motives and applications are different from the related fields in the prior art. That is, only a part of the test pin protector structure 1, corresponding in position to the test pin 20, is made of the conductive material, and the rest of the test pin protector structure 1 is made of the insulating material.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A test pin contact buffer, fixedly connected to a test pin base, for the test pin base to perform electrical or signal detection for an object to be tested, the test pin base having at least one test pin, the test pin having a detecting end, characterized by:
the test pin contact buffer being a sheet-like structure made of a composite material including a conductive material and an insulating material, the test pin contact buffer defining at least one contact area corresponding to the test pin, the contact area having at least one cutout hole, an insulating deformation structure and a conductive head structure, the insulating deformation structure being extendable and made of the insulating material and extending outward from the conductive head structure, the cutout hole enabling the contact area to be in a partial hollow state to facilitate extension and deformation of the insulating deformation structure, a first side of the conductive head structure being in close contact with the detecting end, an opposite second side of the conductive head structure being in contact with the object to be tested when actuated; wherein after the test pin contact buffer is mounted to the test pin base, the detecting end of the test pin is pressed against and in contact with the first side of the conductive head structure under normal condition, and the insulating deformation structure is deformed into a three-dimensional shape due to the conductive head structure under stress.

2. The test pin contact buffer as claimed in claim 1, wherein the cutout hole has a spiral shape, the insulating deformation structure is in the form of a sheet-like spiral structure corresponding to the cutout hole having the spiral shape, the conductive head structure is located at a distal end of the spiral structure, after the insulating deformation structure is deformed, the insulating deformation structure changes from the sheet-like spiral structure to a three-dimensional spiral structure under stress to surround the detecting end and is gradually reduced from the test pin toward the conductive head structure.

3. The test pin contact buffer as claimed in claim 2, wherein the insulating deformation structure further has at least one raised positioning portion, and the raised positioning portion extends from an edge of the insulating deformation structure toward the cutout hole.

4. The test pin contact buffer as claimed in claim 2, wherein the conductive head structure has a hardness less than that of the detecting end so that the detecting end is pressed against the conductive head structure in a piercing manner, when the detecting end pierces the conductive head structure, the conductive head structure is correspondingly formed with at least one micro recess.

5. The test pin contact buffer as claimed in claim 4, wherein the micro recess has a depth that is 10% to 75% of a thickness of the conductive head structure.

6. The test pin contact buffer as claimed in claim 2, further having at least one locking hole, the locking hole being located adjacent to an edge of the test pin contact buffer, the test pin contact buffer being locked to the test pin base by at least one locking member.

7. The test pin contact buffer as claimed in claim 6, wherein the second side that is configured to get contact with the object to be tested of the conductive head structure is provided with a plurality of microstructures, and each of the microstructures has a tip.

8. The test pin contact buffer as claimed in claim 5, further having a first magnetic assembly disposed outside the contact area, the test pin base having a second magnetic assembly, the test pin contact buffer being magnetically coupled to the test pin base so that the conductive head structure is aligned with and fixed to the detecting end.

9. The test pin contact buffer as claimed in claim 5, wherein an inside of the insulating deformation structure is mixed with a plurality of metal particles or a plurality of graphene particles, the metal particles and the graphene particles are covered by the insulating material to block electromagnetic interference and radio frequency interference during detection.

10. The test pin contact buffer as claimed in claim 1, wherein the cutout hole includes a plurality of cutout holes, the cutout holes surround the conductive head structure and are spaced apart from each other to form a circle or a rectangle.

11. The test pin contact buffer as claimed in claim 10, wherein the cutout holes are arranged in the form of a plurality of circles, the insulating deformation structure has a plurality of annular portions and a plurality of connecting portions, one of the annular portions is connected to the conductive head structure, other annular portions are spaced and arranged outwardly in a concentric manner, every two of the annular portions are connected through at least one of the connecting portions, and a corresponding one of the cutout holes is disposed between every adjacent two of the annular portions.

12. The test pin contact buffer as claimed in claim 3, further having at least one locking hole, the locking hole being located adjacent to an edge of the test pin contact buffer, the test pin contact buffer being locked to the test pin base by at least one locking member.

13. The test pin contact buffer as claimed in claim 12, wherein the second side that is configured to get contact with the object to be tested of the conductive head structure is provided with a plurality of microstructures, and each of the microstructures has a tip.

14. The test pin contact buffer as claimed in claim 4, further having at least one locking hole, the locking hole being located adjacent to an edge of the test pin contact buffer, the test pin contact buffer being locked to the test pin base by at least one locking member.

15. The test pin contact buffer as claimed in claim 14, wherein the second side that is configured to get contact with the object to be tested of the conductive head structure is provided with a plurality of microstructures, and each of the microstructures has a tip.

16. The test pin contact buffer as claimed in claim 5, further having at least one locking hole, the locking hole being located adjacent to an edge of the test pin contact buffer, the test pin contact buffer being locked to the test pin base by at least one locking member.

17. The test pin contact buffer as claimed in claim 16, wherein the second side that is configured to get contact with the object to be tested of the conductive head structure is provided with a plurality of microstructures, and each of the microstructures has a tip.
